(19) United States
(12) Patent Application Publication
(10) Pub. No.: US 2024/0397672 A1
(43) Pub. Date: Nov. 28, 2024

(54) REDUCING ENERGY CONSUMED FOR COOLING EQUIPMENT IN AN EDGE CONTAINER

(71) Applicant: International Business Machines Corporation, Armonk, NY (US)

(72) Inventors: Dustin Demetriou, New York, NY (US); John S. Werner, Fishkill, NY (US); Arkadiy O. Tsfasman, Wappingers Falls, NY (US); John Torok, Poughkeepsie, NY (US); Noah Singer, White Plains, NY (US)

(21) Appl. No.: 18/202,789

(22) Filed: May 26, 2023

(51) Int. Cl. H05K 7/20

(52) U.S. Cl. CPC H05K 7/20745; H05K 7/20145; H05K 7/20418

(57) ABSTRACT

Described is an edge container of an edge data center that includes information technology (IT) racks holding IT equipment. Furthermore, the edge container includes at least one air conditioning unit configured to provide cool air to an aisle which enters an inlet side of the IT racks. Additionally, the edge container includes an economizer that includes an internal and an external heat exchanger. The economizer is then activated to increase a transfer of heat/cooling between an internal environment of the edge container and an external environment in response to a reading of an environmental condition being below a temperature of exhaust air in a hot aisle of the edge container which exits an outlet side of the IT racks. If, however, the reading of the external environmental condition is not below the temperature of the exhaust air in the hot aisle of the edge container, then the economizer is deactivated.

### TECHNICAL FIELD

The present disclosure relates generally to edge data centers, and more particularly to reducing the energy consumed for cooling equipment (e.g., information technology (IT) equipment) in an edge container of the edge data center.

### BACKGROUND

Edge data centers are small data centers that are located close to the edge of a network. They provide the same devices found in traditional data centers, but are contained in a smaller footprint, closer to end users and devices. Edge data centers can deliver cached content and cloud computing resources to these devices. The concept works off edge computing, which is a distributed information technology (IT) architecture where client data is processed as close to the originating source as possible. Because the smaller data centers are positioned close to the end users, they are used to deliver fast services with minimal latency.

### SUMMARY

In one embodiment of the present disclosure, an edge container of an edge data center comprises information technology racks holding information technology equipment. The edge container further comprises at least one air conditioning unit configured to provide cool air to a cold aisle which enters an inlet side of the information technology racks. The edge container additionally comprises an economizer comprising an internal heat exchanger and an external heat exchanger, where the economizer is activated to increase a transfer of heat/cooling between an internal environment of the edge container and an external environment in response to a reading of an external environmental condition being below a temperature of exhaust air in a hot aisle of the edge container which exits an outlet side of the information technology racks.

In another embodiment of the present disclosure, a method for transferring heat from an internal environment of an edge container of an edge data center to an external environment comprises extracting a reading of an external environmental condition. The method additionally comprises activating an economizer of the edge container to increase a transfer of heating or cooling between the internal environment of the edge container and the external environment in response to the read environmental condition being below a temperature of exhaust air in a hot aisle of the edge container which exits an outlet side of information technology racks.

Other forms of the embodiment of the method described above are in a system and in a computer program product.

The foregoing has outlined rather generally the features and technical advantages of one or more embodiments of the present disclosure in order that the detailed description of the present disclosure that follows may be better understood. Additional features and advantages of the present disclosure will be described hereinafter which may form the subject of the claims of the present disclosure.

### BRIEF DESCRIPTION OF THE DRAWINGS

A better understanding of the present disclosure can be obtained when the following detailed description is considered in conjunction with the following drawings, in which:

FIG. 1 illustrates an embodiment of an edge container with an integrated economizer (ECIE) in accordance with an embodiment of the present disclosure;

FIG. 2 illustrates an airflow simulation of the ECIE of FIG. 1 in accordance with an embodiment of the present disclosure;

FIG. 3 illustrates an alternative embodiment of the ECIE where the fins of the external heat exchanger can be folded up or down to control the amount of heat transfer in accordance with an embodiment of the present disclosure;

FIGS. 4A-4B illustrate an alternative embodiment of the ECIE where the fins of the internal heat exchanger can be exposed or blocked to control the amount of heat transfer in accordance with an embodiment of the present disclosure;

FIG. 5 illustrates an embodiment of the present disclosure of the hardware configuration of the ECIE which is representative of a hardware environment for practicing the present disclosure;

FIG. 6 is a flowchart of a method for reducing energy consumed in connection with transferring heat/cooling between an internal environment of the edge container of an edge data center and an external environment using a cumulative environmental operation range for all the equipment in accordance with an embodiment of the present disclosure; and

FIG. 7 is a flowchart of a method for reducing energy consumed by the air conditioning unit in connection with transferring heat/cooling between an internal environment of the edge container of the edge data center and an external environment using operational limits of classes of data center equipment and desired setpoints within an operational range in accordance with an embodiment of the present disclosure.

### DETAILED DESCRIPTION

As stated above, edge data centers are small data centers that are located close to the edge of a network. They provide the same devices found in traditional data centers, but are contained in a smaller footprint, closer to end users and devices. Edge data centers can deliver cached content and cloud computing resources to these devices. The concept works off edge computing, which is a distributed information technology (IT) architecture where client data is processed as close to the originating source as possible. Because the smaller data centers are positioned close to the end users, they are used to deliver fast services with minimal latency.

Edge data centers include decentralized computing resources, which may be installed in “edge containers,” located as close as possible to the end user in order to reduce latency, save bandwidth, and enhance the overall digital experience. Edge containers are becoming increasing popular due to their quick deployment, scalability capacity for implementation anywhere, and the ability to protect the internal computing resources.

Edge containers typically employ a mechanical-based cooling system to provide cooling to the IT equipment. IT equipment includes computers and associated peripheral devices, computer operating systems, utility/support software, communications hardware and software, etc.

Cooling systems in such edge containers require external electricity, which may be extensive. As a result, the energy consumed for cooling the IT equipment in the edge container needs to be reduced in order to more efficiently use power resources.

The embodiments of the present disclosure provide a means for reducing the energy consumed for cooling equipment in the edge container of the edge data center. In particular, in one embodiment, the heat/cooling transfer between the internal and external environments of the edge container is improved thereby reducing the overall mechanical cooling power consumption as discussed further below.

In some embodiments of the present disclosure, the present disclosure comprises an edge container of an edge data center that includes information technology racks holding information technology (IT) equipment. The IT equipment includes computers and associated peripheral devices, computer operating systems, utility/support software, communications hardware and software, etc. Furthermore, the edge container includes at least one air conditioning unit configured to provide cool air to a cold aisle which enters an inlet side of the information technology racks. Additionally, the edge container includes an economizer that includes an internal heat exchanger and an external heat exchanger. In one embodiment, a cumulative environmental operation range (e.g., range of temperature, range of humidity, range of pressure) of all the equipment of the edge container is determined. For example, if a first IT equipment has an operational range of 10° C.-40° C. and a second IT equipment has an operational range of 5° C.-35° C., then the cumulative environmental operation range is 10° C.-35° C. since this is the safe operational range for the first and second IT equipment. The economizer is then activated to increase the transfer of heat/cooling between an internal environment of the edge container and an external environment in response to a reading of an environmental condition (e.g., temperature, pressure, humidity, etc.) in the external environment that would lead to reduced energy consumption for the cooling equipment to maintain environmental conditions within the cumulative environmental operation range. An “environmental condition,” as used herein, refers to a state of the environment, such as the temperature, pressure, humidity, etc. of the environment. If, however, the reading of the environmental condition (e.g., temperature, pressure, humidity, etc.) in the external environment would not lead to reduced energy consumption for the cooling equipment to maintain environmental conditions within the cumulative environmental operation range, then the economizer is deactivated thereby reducing the transfer of heat/cooling between the internal environment of the edge container and the external environment. In this manner, the energy consumed for cooling equipment (e.g., IT equipment) in the edge container of the edge data center is reduced. In particular, the heat/cooling transfer between the internal and external environments of the edge container is improved thereby reducing the overall mechanical cooling power consumption.

In the following description, numerous specific details are set forth to provide a thorough understanding of the present disclosure. However, it will be apparent to those skilled in the art that the present disclosure may be practiced without such specific details. In other instances, well-known circuits have been shown in block diagram form in order not to obscure the present disclosure in unnecessary detail. For the most part, details considering timing considerations and the like have been omitted inasmuch as such details are not necessary to obtain a complete understanding of the present disclosure and are within the skills of persons of ordinary skill in the relevant art.

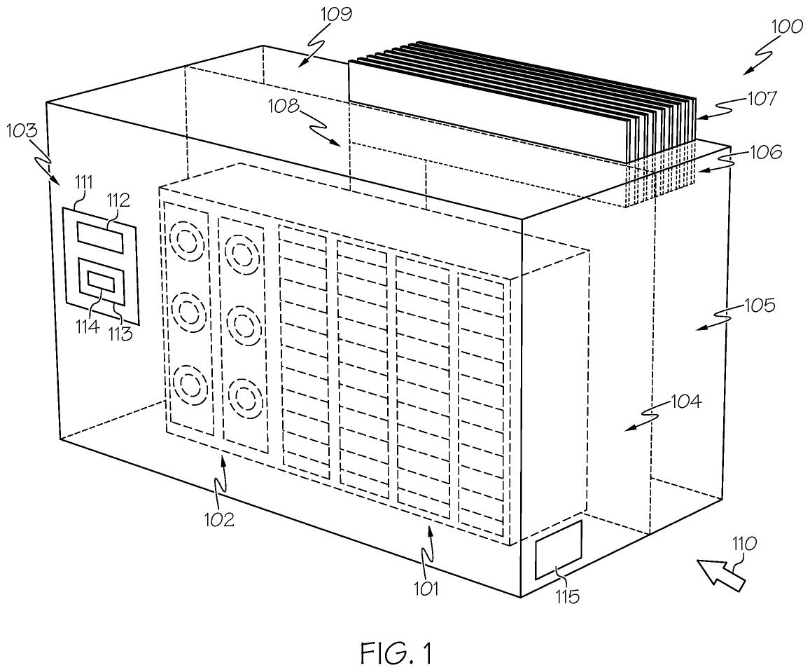

Referring now to the Figures in detail, FIG. 1 illustrates an embodiment of an edge container with an integrated economizer (ECIE) 100 in accordance with an embodiment of the present disclosure.

As shown in FIG. 1, ECIE 100 includes information technology (IT) equipment racks 101, air conditioning units (ACUs) 102, a cold aisle 103, an aisle separator 104, an IT exhaust plenum (“hot aisle”) 105, an internal heat exchanger 106, an external heat exchanger 107, a plenum separator 108, a mechanical air conditioner plenum 109, external air 110, a data center infrastructure management (DCIM) 111 and sensors 115.

An IT equipment rack 101 corresponds to a frame or enclosure for holding or mounting IT equipment as well as the IT equipment within said frame or enclosure. IT equipment includes computers and associated peripheral devices, computer operating systems, utility/support software, communications hardware and software, etc.

In one embodiment, cool air enters the front of IT equipment racks 101 (referred to as the “cold aisle” 103) and hot air exits the back of IT equipment racks 101 (referred to as the “hot aisle” or IT exhaust plenum 105).

In one embodiment, ACUs 102 provide cool air using blowers or fans and a radiator and/or using a refrigerant based cooling system, to cold aisle 103, which enters the inlet side of IT equipment racks 101. Internal and external heat exchangers (i.e., the economizer) may be used to ensure cooler air is circulated back to ACU 102 such that it does not have to use as much energy to further cool the air before blowing cool air into cold aisle 103 again.

In one embodiment, aisle separator 104 ensures that the cold aisle 103 (front of IT equipment racks 101 and ACUs 102) is separated from the hot aisle (IT exhaust plenum 105).

In one embodiment, IT exhaust plenum 105 (hot aisle) is a chamber for the hot air exiting IT equipment racks 101.

In one embodiment, internal heat exchanger 106 and external heat exchanger 107 form the “economizer” of the present disclosure. An “economizer,” as used herein, is a type of heat exchanger that recovers heat from gasses to preheat fluids or puts it to use in another part of the production process. Such a recovery process saves on fuel consumption and costs as well as reduces the CO₂ emission.

In one embodiment, plenum separator 108 is configured to separate the airflow exhausted from IT equipment racks 101 from the airflow exhausted to the mechanical air conditioner plenum 109 before entering one or more of the ACUs 102.

In one embodiment, DCIM 111 provides the oversite and operation of ECIE 100. In particular, DCIM 111 is utilized to discover, monitor, report, and visualize operations of ECIE 100. In one embodiment, DCIM 111 is configured to improve the heat/cooling transfer between the internal and external environments of the edge container thereby reducing the overall mechanical cooling power consumption as discussed further below. The “internal environment,” as used herein, refers to the environment within the edge container or ECIE, such as ECIE 100. The “external environment,” as used herein, refers to the environment outside the edge container or ECIE, such as ECIE 100.

In one embodiment, DCIM 111 includes a processor 112 and a memory 113. In one embodiment, an application 114, such as a program for improving the heat/cooling transfer between the internal and external environments of the edge container thereby reducing the overall mechanical cooling power consumption, may be loaded into memory 113. Examples of memory 113 include random access memory (RAM), dynamic RAM (DRAM), static RAM (SRAM), read-only memory (ROM), programmable ROM (PROM), erasable PROM (EPROM), electrically erasable PROM (EEPROM), an optical drive, a solid-state drive, etc. In one embodiment, processor 112 is configured to execute the instructions of a program, such as application 114.

In one embodiment, DCIM 111 is a separate monitoring/computing device. In one embodiment, DCIM 111 is located on the wall of ECIE 100. In one embodiment, DCIM 111 is located in IT equipment racks 101. In one embodiment, DCIM 111 runs off of IT equipment of IT equipment racks 101.

Additionally, ECIE 100 includes various sensors, such as sensors 115, to capture the environmental conditions, both internally and externally of ECIE 100. Such environmental conditions include temperature, pressure, humidity, etc. In one embodiment, sensors 115 are placed both internally and externally to the ECIE, such as ECIE 100, including being attached to equipment, such as IT equipment, ACUs 102 and the economizer, in the IT exhaust plenum 105 (hot aisle), in the cold aisle 103, etc. In one embodiment, DCIM 111 acquires such sensor data from sensor 115 using various software tools, including, but not limited to, Data Capture Lab, etc. Examples of sensors 115 include, but are not limited to, pressure sensors (e.g., differential air pressure sensor), temperature sensors (e.g., DX2-T1 by Raritan®), humidity sensors (e.g., DX2-T1H1 by Raritan®), etc.

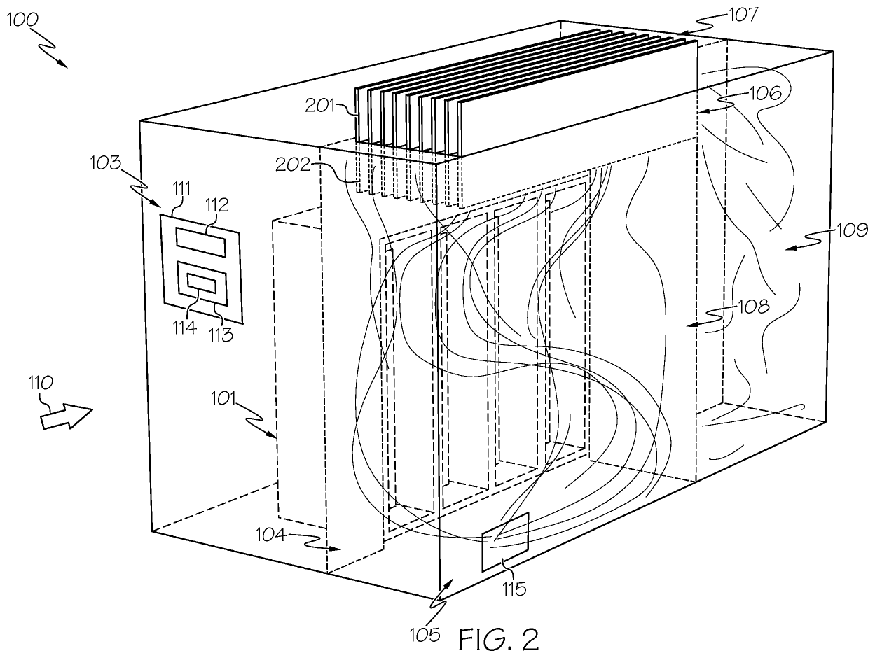

A further discussion regarding the components of ECIE 100 is provided below in connection with FIGS. 2-3, 4A-4B, and 5-7.

A discussion regarding an airflow simulation of ECIE 100 of FIG. 1 is provided below in connection with FIG. 2.

Referring to FIG. 2, FIG. 2 illustrates an airflow simulation of ECIE 100 of FIG. 1 in accordance with an embodiment of the present disclosure.

As shown in FIG. 2, airflow exhausts from IT equipment racks 101 and is contained within IT exhaust plenum 105 (hot aisle).

In one embodiment, airflow is ducted through internal heat exchanger 106 due to the opening at the end of internal heat exchanger 106 above plenum separator 108 to mechanical air conditioner plenum 109.

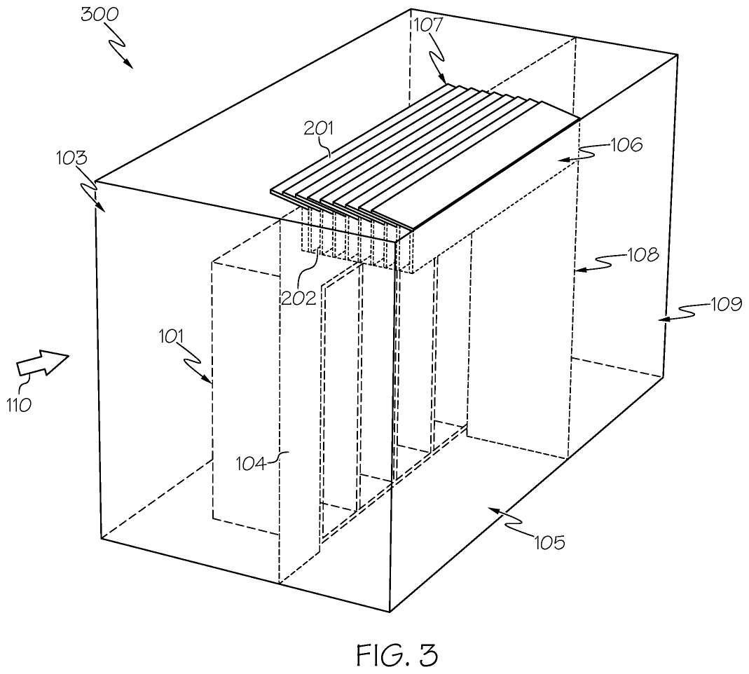

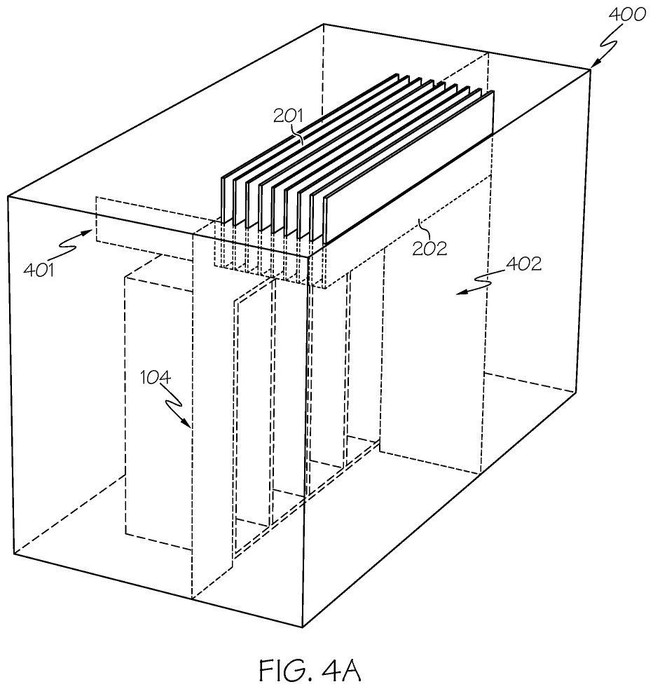

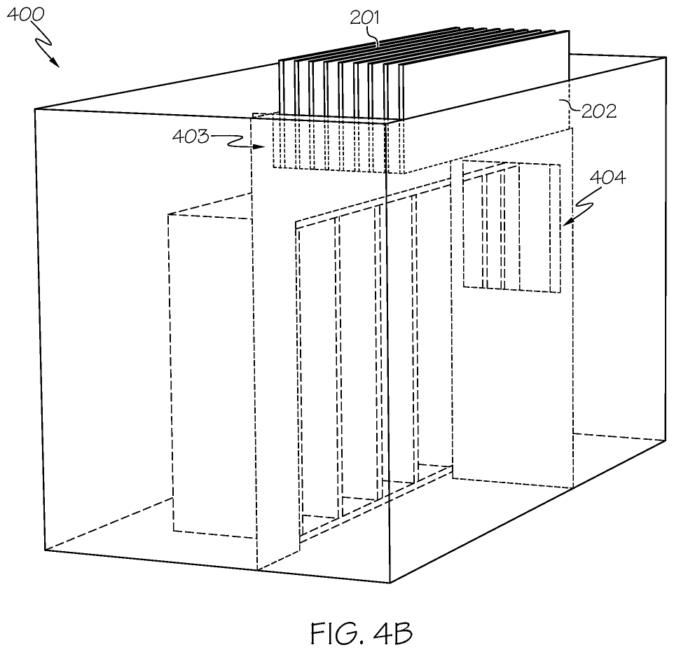

In one embodiment, heat from the air stream is transferred to the outside environment via external heat exchanger 107. In one embodiment, external air 110 flows through fins 201 of external heat exchanger 107 allowing cool external air to transfer into ECIE 100. The economizer, when in use, reaches an equilibrium temperature between the external air temperature and the temperature of the air inside IT exhaust plenum 105. This allows for cooler air to be transferred to mechanical air conditioner plenum 109. A further discussion of fins 201 of external heat exchanger 107 is provided below in connection with FIG. 3. Fins 202 of internal heat exchanger 106 are also shown in FIG. 2. A further discussion of fins 202 of internal heat exchanger 106 is provided below in connection with FIGS. 4A-4B.

In one embodiment, cooler external air 110 removes more heat from IT exhaust plenum 105. Furthermore, in one embodiment, one or more fans could be added on top of ECIE 100 that blow external air 110 through external heat exchanger 107.

In one embodiment, airflow is exhausted into mechanical air conditioner plenum 109 before entering ACUs 102 for the remaining cooling needs. As illustrated in FIG. 2, the temperature within mechanical air conditioner plenum 109 is greatly reduced thereby ensuring that ACUs 102 will draw less power leading to lower operation cost (reduced carbon footprint).

Referring now to FIG. 3, FIG. 3 illustrates ECIE 300, which is an alternative embodiment of ECIE 100 of FIGS. 1 and 2 where the fins (e.g., fins 201 of FIG. 2) of the external heat exchanger (e.g., external heat exchanger 107 of FIGS. 1 and 2) can be folded up or down to control the amount of heat transfer in accordance with an embodiment of the present disclosure. In one embodiment, fins 201 of external heat exchanger 107 are folded down when the economizer is deactivated (i.e., when the economizer is reducing the transfer of heat/cooling between the internal environment of the edge container and the external environment). In one embodiment, fins 201 of external heat exchanger 107 are folded up when the economizer is activated (i.e., when the economizer is increasing the transfer of heat/cooling between the internal environment of the edge container and the external environment).

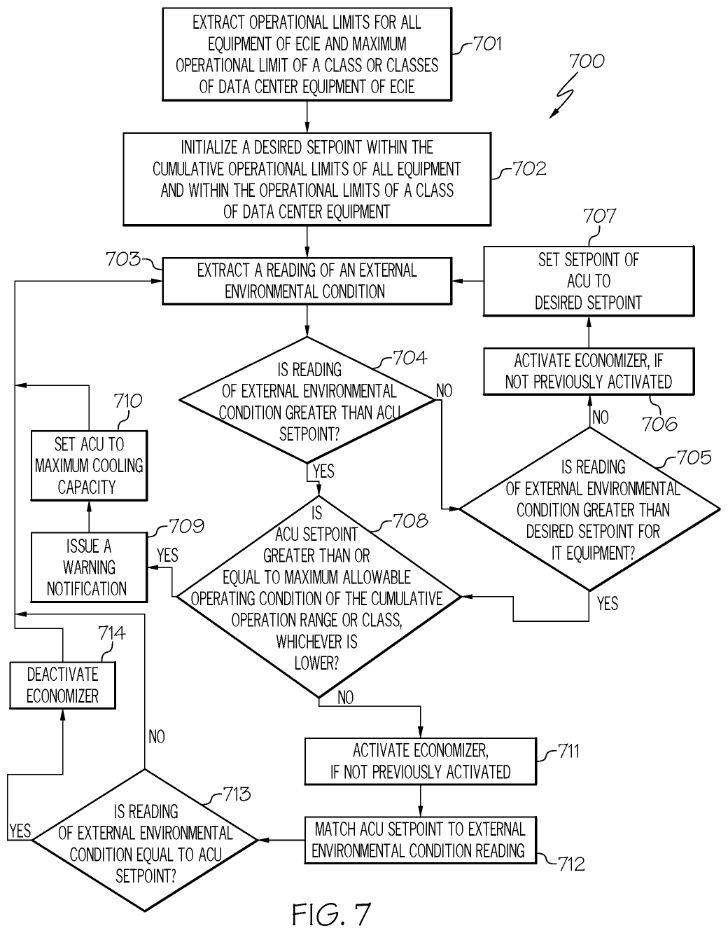

As shown in FIG. 3, ECIE 300 includes the same components of ECIE 100 of FIGS. 1 and 2 with external heat exchanger 107 being in a retracted position when the economizer is deactivated (i.e., when the economizer is reducing the transfer of heat/cooling between the internal environment of the edge container and the external environment). In particular, fins 201 of external heat exchanger 107 are folded down in such a retracted position. In one embodiment, fins 201 are folded downward in order to minimize or prevent the effects of the temperature of external air 110 from heating up the inside of ECIE 300 or when external air 110 is below a temperature that could lead to ACU 102 blowing air into cold aisle 103 that is below the operational minimum of at least a portion of the IT equipment of IT equipment racks 101, such as during the state of ECIE 300 when external air 110 is at a higher temperature than desired and/or higher than a temperature that would lead to reduced energy consumption for the cooling equipment to maintain environmental conditions at the current ACU setpoint as discussed below in connection with FIG. 7. In another embodiment, fins 202 of internal heat exchanger 106 fold upwards in order to minimize or prevent the effects of the temperature of external air 110 from heating up the inside of ECIE 300 or when external air 110 is below a temperature that could lead to ACU 102 blowing air into cold aisle 103 that is below the operational minimum of at least a portion of the IT equipment of IT equipment racks 101, such as during the state of ECIE 300 when external air 110 is at a higher temperature than desired and/or higher than a temperature that would lead to reduced energy consumption for the cooling equipment to maintain environmental conditions at the current ACU setpoint.

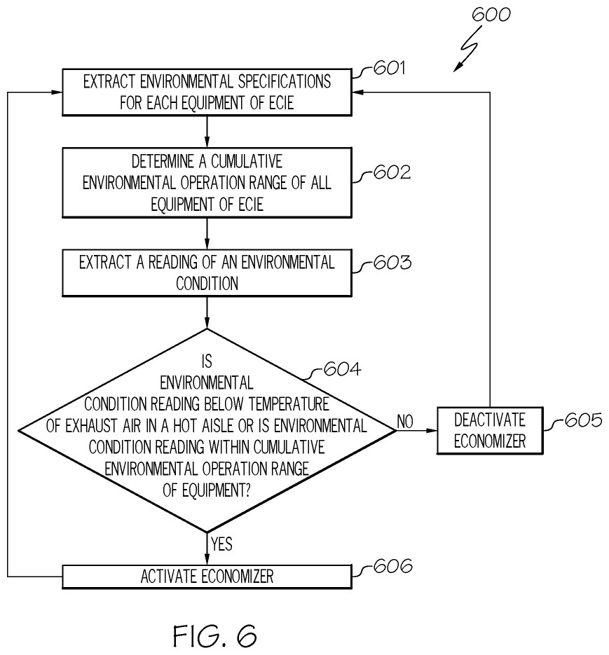

In one embodiment, a compressible thermal interface material (TIM) is used between the bottom of fins 201 on the retracted external heat exchanger 107 that gets compressed and improves heat transfer when the economizer is activated/operational (fins 201 are up when the economizer is activated/operational) as discussed further below in connection with FIGS. 6-7.

Referring now to FIGS. 4A-4B, FIGS. 4A-4B illustrate ECIE 400, which is an alternative embodiment of ECIE 100 of FIGS. 1 and 2 where the fins (e.g., fins 202 of FIG. 2) of the internal heat exchanger (e.g., internal heat exchanger 106 of FIGS. 1 and 2) can be exposed or blocked to control the amount of heat transfer in accordance with an embodiment of the present disclosure.

As shown in FIGS. 4A-4B, ECIE 400 includes the same components of ECIE 100 of FIGS. 1 and 2 while additionally including an internal heat exchanger blocking baffle and a plenum separator window.

A baffle, as used herein, is a flow-directing or obstructing vane or panel used to direct a flow of liquid or gas. A blocking baffle, as used herein, refers to a piece of material (e.g., metal, plastic, etc.), sometimes hollow, used to baffle or deflect the flow of liquid or gas.

A plenum separator window, as used herein, refers to a divider to separate the airflows of two or more chambers.

FIG. 4A illustrates an economizer being operational (i.e., activated) with the internal heat exchanger blocking baffle being open 401 and the plenum separator window being closed 402. As previously discussed, when the economizer is activated, the economizer increases the transfer of heat/cooling between the internal environment of the edge container and the external environment.

FIG. 4B illustrates the economizer being deactivated with the internal heat exchanger blocking baffle being closed 403 and the plenum separator window being open 404. As previously discussed, when the economizer is deactivated, the economizer reduces the transfer of heat/cooling between the internal environment of the edge container and the external environment.

In one embodiment, the exhaust air from the IT equipment in IT equipment racks 101 now returns to ACU 102 through window 404 and does not flow through internal heat exchanger 106. In one embodiment, internal heat exchanger 106 in this configuration is at an equilibrium temperature with external heat exchanger 107 that would force ACUs 102 to utilize more energy or have the temperature outputted by ACU 102 into cold aisle 103 be outside the operational range of the IT equipment of IT equipment racks 101.

In an alternative embodiment, plenum separator 108 does not have a window and is hinged at the top of ECIE 400. In such an embodiment, plenum separator 108 is motor controlled to be raised upwards such that the bottom of plenum separator 108 extends across fins 202 of internal heat exchanger 106 for even greater prevention of heat transfer from the economizer.

A discussion regarding the methods for transferring heat/cooling between an internal environment of the edge container of the edge data center (e.g., ECIE 300, 400) and an external environment using the various embodiments of ECIE discussed above, such as in FIGS. 1-3 and 4A-4B, is provided below in connection with FIGS. 6-7.

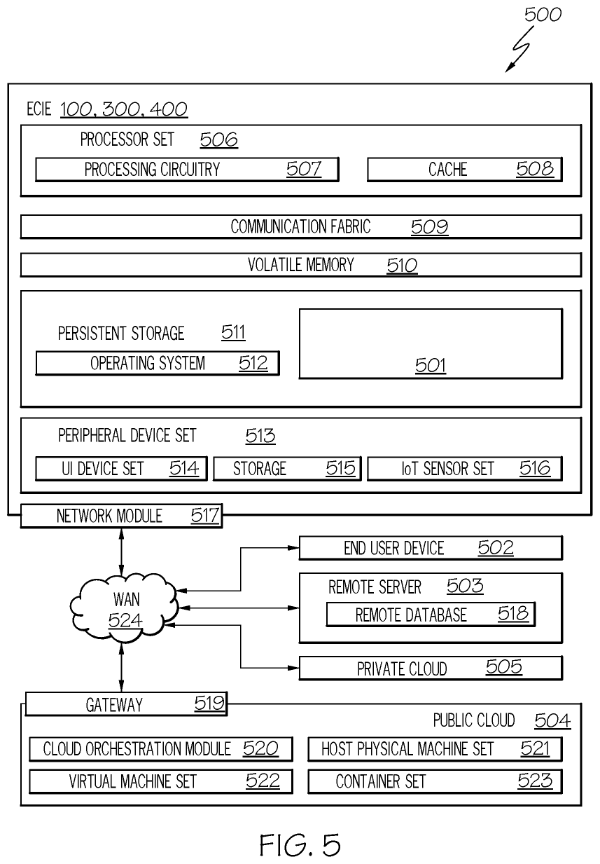

Referring now to FIG. 5, FIG. 5 illustrates an embodiment of the present disclosure of the hardware configuration of ECIE 100, 300, 400 which is representative of a hardware environment for practicing the present disclosure.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 500 contains an example of an environment for the execution of at least some of the computer code (computer code, which is stored in block 501, for improving the heat/cooling transfer between the internal and external environments of the edge container) involved in performing the disclosed methods, such as improving the heat/cooling transfer between the internal and external environments of the edge container thereby reducing the overall mechanical cooling power consumption. In addition to block 501, computing environment 500 includes, for example, ECIE 100, 300, 400, wide area network (WAN) 524, end user device (EUD) 502, remote server 503, public cloud 504, and private cloud 505. In this embodiment, ECIE 100, 300, 400 includes processor set 506 (including processing circuitry 507 and cache 508), communication fabric 509, volatile memory 510, persistent storage 511 (including operating system 512 and block 501, as identified above), peripheral device set 513 (including user interface (UI) device set 514, storage 515, and Internet of Things (IoT) sensor set 516), and network module 517. Remote server 503 includes remote database 518. Public cloud 504 includes gateway 519, cloud orchestration module 520, host physical machine set 521, virtual machine set 522, and container set 523.

ECIE 100, 300, 400 may take the form of any computing device now known or to be developed in the future that is capable of running a program, accessing a network or querying a database, such as remote database 518. As is well understood in the art of computer technology, and depending upon the technology, performance of a computer-implemented method may be distributed among multiple computers and/or between multiple locations. On the other hand, in this presentation of computing environment 500, detailed discussion is focused on a single computer, specifically ECIE 100, 300, 400, to keep the presentation as simple as possible. ECIE 100, 300, 400 may be located in a cloud, even though it is not shown in a cloud in FIG. 5. On the other hand, ECIE 100, 300, 400 is not required to be in a cloud except to any extent as may be affirmatively indicated.

Processor set 506 includes one, or more, computer processors of any type now known or to be developed in the future. Processing circuitry 507 may be distributed over multiple packages, for example, multiple, coordinated integrated circuit chips. Processing circuitry 507 may implement multiple processor threads and/or multiple processor cores. Cache 508 is memory that is located in the processor chip package(s) and is typically used for data or code that should be available for rapid access by the threads or cores running on processor set 506. Cache memories are typically organized into multiple levels depending upon relative proximity to the processing circuitry. Alternatively, some, or all, of the cache for the processor set may be located “off chip.” In some computing environments, processor set 506 may be designed for working with qubits and performing quantum computing.

Computer readable program instructions are typically loaded onto ECIE 100, 300, 400 to cause a series of operational steps to be performed by processor set 506 of ECIE 100, 300, 400 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 508 and the other storage media discussed below. The program instructions, and associated data, are accessed by processor set 506 to control and direct performance of the inventive methods. In computing environment 500, at least some of the instructions for performing the inventive methods may be stored in block 501 in persistent storage 511.

Communication fabric 509 is the signal conduction paths that allow the various components of ECIE 100, 300, 400 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 510 is any type of volatile memory now known or to be developed in the future. Examples include dynamic type random access memory (RAM) or static type RAM. Typically, the volatile memory is characterized by random access, but this is not required unless affirmatively indicated. In ECIE 100, 300, 400, the volatile memory 510 is located in a single package and is internal to ECIE 100, 300, 400, but, alternatively or additionally, the volatile memory may be distributed over multiple packages and/or located externally with respect to ECIE 100, 300, 400.

Persistent Storage 511 is any form of non-volatile storage for computers that is now known or to be developed in the future. The non-volatility of this storage means that the stored data is maintained regardless of whether power is being supplied to ECIE 100, 300, 400 and/or directly to persistent storage 511. Persistent storage 511 may be a read only memory (ROM), but typically at least a portion of the persistent storage allows writing of data, deletion of data and re-writing of data. Some familiar forms of persistent storage include magnetic disks and solid state storage devices. Operating system 512 may take several forms, such as various known proprietary operating systems or open source Portable Operating System Interface type operating systems that employ a kernel. The code included in block 501 typically includes at least some of the computer code involved in performing the inventive methods.

Peripheral device set 513 includes the set of peripheral devices of ECIE 100, 300, 400. Data communication connections between the peripheral devices and the other components of ECIE 100, 300, 400 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 514 may include components such as a display screen, speaker, microphone, wearable devices (such as goggles and smart watches), keyboard, mouse, printer, touchpad, game controllers, and haptic devices. Storage 515 is external storage, such as an external hard drive, or insertable storage, such as an SD card. Storage 515 may be persistent and/or volatile. In some embodiments, storage 515 may take the form of a quantum computing storage device for storing data in the form of qubits. In embodiments where ECIE 100, 300, 400 is required to have a large amount of storage (for example, where ECIE 100, 300, 400 locally stores and manages a large database) then this storage may be provided by peripheral storage devices designed for storing very large amounts of data, such as a storage area network (SAN) that is shared by multiple, geographically distributed computers. IoT sensor set 516 is made up of sensors that can be used in Internet of Things applications. For example, one sensor may be a thermometer and another sensor may be a motion detector.

Network module 517 is the collection of computer software, hardware, and firmware that allows ECIE 100, 300, 400 to communicate with other computers through WAN 524. Network module 517 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 517 are performed on the same physical hardware device. In other embodiments (for example, embodiments that utilize software-defined networking (SDN)), the control functions and the forwarding functions of network module 517 are performed on physically separate devices, such that the control functions manage several different network hardware devices. Computer readable program instructions for performing the inventive methods can typically be downloaded to ECIE 100, 300, 400 from an external computer or external storage device through a network adapter card or network interface included in network module 517.

WAN 524 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 502 is any computer system that is used and controlled by an end user (for example, a customer of an enterprise that operates ECIE 100, 300, 400), and may take any of the forms discussed above in connection with ECIE 100, 300, 400. EUD 502 typically receives helpful and useful data from the operations of ECIE 100, 300, 400. For example, in a hypothetical case where ECIE 100, 300, 400 is designed to provide a recommendation to an end user, this recommendation would typically be communicated from network module 517 of ECIE 100, 300, 400 through WAN 524 to EUD 502. In this way, EUD 502 can display, or otherwise present, the recommendation to an end user. In some embodiments, EUD 502 may be a client device, such as thin client, heavy client, mainframe computer, desktop computer and so on.

Remote server 503 is any computer system that serves at least some data and/or functionality to ECIE 100, 300, 400. Remote server 503 may be controlled and used by the same entity that operates ECIE 100, 300, 400. Remote server 503 represents the machine(s) that collect and store helpful and useful data for use by other computers, such as ECIE 100, 300, 400. For example, in a hypothetical case where ECIE 100, 300, 400 is designed and programmed to provide a recommendation based on historical data, then this historical data may be provided to ECIE 100, 300, 400 from remote database 518 of remote server 503.

Public cloud 504 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 504 is performed by the computer hardware and/or software of cloud orchestration module 520. The computing resources provided by public cloud 504 are typically implemented by virtual computing environments that run on various computers making up the computers of host physical machine set 521, which is the universe of physical computers in and/or available to public cloud 504. The virtual computing environments (VCEs) typically take the form of virtual machines from virtual machine set 522 and/or containers from container set 523. It is understood that these VCEs may be stored as images and may be transferred among and between the various physical machine hosts, either as images or after instantiation of the VCE. Cloud orchestration module 320 manages the transfer and storage of images, deploys new instantiations of VCEs and manages active instantiations of VCE deployments. Gateway 519 is the collection of computer software, hardware, and firmware that allows public cloud 504 to communicate through WAN 524.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 505 is similar to public cloud 504, except that the computing resources are only available for use by a single enterprise. While private cloud 505 is depicted as being in communication with WAN 524 in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 504 and private cloud 505 are both part of a larger hybrid cloud.

Block 501 further includes software components to improve the heat/cooling transfer between the internal and external environments of the edge container thereby reducing the overall mechanical cooling power consumption. In one embodiment, such components may be implemented in hardware. The functions discussed herein performed by such components are not generic computer functions. As a result, ECIC 100, 300, 400 is a particular machine that is the result of implementing specific, non-generic computer functions.

In one embodiment, the functionality of such software components, including the functionality for improving the heat/cooling transfer between the internal and external environments of the edge container thereby reducing the overall mechanical cooling power consumption, may be embodied in an application specific integrated circuit.

As stated above, edge data centers include decentralized computing resources, which may be installed in “edge containers,” located as close as possible to the end user in order to reduce latency, save bandwidth, and enhance the overall digital experience. Edge containers are becoming increasing popular due to their quick deployment, scalability capacity for implementation anywhere, and the ability to protect the internal computing resources. Edge containers typically employ a mechanical-based cooling system to provide cooling to the IT equipment. IT equipment includes computers and associated peripheral devices, computer operating systems, utility/support software, communications hardware and software, etc. Cooling systems in such edge containers require external electricity, which may be extensive. As a result, the energy consumed for cooling the IT equipment in the edge container needs to be reduced in order to more efficiently use power resources.

The embodiments of the present disclosure provide a means for reducing the energy consumed for cooling equipment (e.g., IT equipment) in the edge container of the edge data center as discussed below in connection with FIGS. 6 and 7. FIG. 6 is a flowchart of a method for reducing energy consumed in connection with transferring heat/cooling between an internal environment of the edge container of the edge data center and an external environment using a cumulative environmental operation range for all the equipment. FIG. 7 is a flowchart of a method for reducing energy consumed by ACU 102 (FIG. 1) in connection with transferring heat/cooling between an internal environment of the edge container of the edge data center and an external environment using operational limits of classes of data center equipment and desired setpoints within an operational range.

As stated above, FIG. 6 is a flowchart of a method 600 for reducing energy consumed in connection with transferring heat/cooling between an internal environment of the edge container of an edge data center (e.g., ECIE 100, 300, 400) and an external environment using a cumulative environmental operation range for all the equipment within the edge container (e.g., ECIE 100, 300, 400) in accordance with an embodiment of the present disclosure.

Referring to FIG. 6, in conjunction with FIGS. 1-3, 4A-4B, and 5, in operation 601, DCIM 111 extracts the environmental specifications for each equipment of ECIE 100, 300, 400. “Environmental specifications,” as used herein, refer to operational constraints of the equipment of ECIE 100, 300, 400 involving environmental conditions, such as temperature, pressure, humidity, etc. Equipment of ECIE 100, 300, 400, includes, for example, the IT equipment of IT equipment racks 101, ACUs 102, economizer, etc.

In one embodiment, DCIM 111 extracts the environmental specifications for each equipment of ECIE 100, 300, 400 from data stored on the equipment. In one embodiment, DCIM 111 extracts the environmental specifications for each equipment of ECIE 100, 300, 400 from public records (e.g., product datasheets). In one embodiment, DCIM 111 extracts the environmental specifications for each equipment of ECIE 100, 300, 400 by receiving such information from the operators of ECIE 100, 300, 400 and internal equipment.

For example, a single server within IT equipment rack 101 may have an operational temperature range from 5° C.-40° C. That is, such a server should not be utilized outside this temperature range.

In operation 602, DCIM 111 determines the cumulative environmental operation range of all the equipment of ECIE 100, 300, 400. That is, DCIM 111 aggregates the environmental specifications extracted in operation 601 to determine a cumulate environmental operation range (e.g., range of temperature, range of humidity, range of pressure) for all the equipment within ECIE 100, 300, 400.

For example, if a first IT equipment has an operational range of 10° C.-40° C. and a second IT equipment has an operational range of 5° C.-35° C., then the cumulative environmental operation range is 10° C.-35° C. since this is the safe operational range for the first and second IT equipment.

In one embodiment, DCIM 111 utilizes various software tools for determining the cumulative environmental operation range of the equipment based on the extracted environmental specifications of the equipment, including, but not limited to, IBM® SPSS® Statistics, JMP®, Minitab®, OriginPro®, XLSTAT®, etc.

In operation 603, DCIM 111 extracts a reading of an environmental condition, such as temperature, pressure, humidity, etc. In one embodiment, the environmental condition is from an external environment, such as outside ECIE 100, 300, 400. An “environmental condition,” as used herein, refers to a state of the environment, such as the temperature, pressure, humidity, etc. of the environment.

In one embodiment, DCIM 111 extracts such a reading from one or more sensors 115, which are placed internal within and/or external to ECIE 100, 300, 400. Examples of such sensors 115 include, but are not limited to, pressure sensors (e.g., differential air pressure sensor), temperature sensors (e.g., DX2-T1 by Raritan®), humidity sensors (e.g., DX2-T1H1 by Raritan®), etc.

In operation 604, DCIM 111 determines whether the reading of the environmental condition is below a temperature of exhaust air in hot aisle 105 which exits an outlet side of information technology racks 101 or is within the cumulative environmental operation range of the equipment of ECIE 100, 300, 400.

For example, the external air temperature may be above the operational range of the IT equipment of IT equipment racks 101 but below the exhaust air temperature of the IT equipment of IT equipment racks 101. In this example, there is still a benefit from an activated economizer because external air 110 would help cool the IT exhaust air before it returns to ACU 102.

In another example, if DCIM 111 extracts a reading of the external air temperature (e.g., temperature of external air 110 corresponding to 25° C.), then DCIM 111 determines if such a reading is within the cumulative environmental operation range determined in operation 602 (e.g., the cumulative environmental operation range of 10° C.-35° C.). In one embodiment, DCIM 111 utilizes various software tools for determining if a reading is within the cumulative environmental operation range of values, including, but not limited to, IBM® SPSS® Statistics, JMP®, Minitab®, OriginPro®, XLSTAT®, etc.

In an alternative embodiment, DCIM 111 determines if the temperature of external air 110 is outside a temperature range that would make ACU 102 utilize more energy to keep the IT equipment of IT equipment racks 101 within their cumulative operational range.

In one embodiment, if the reading of the environmental condition (e.g., temperature of external air 110 corresponding to 30° C.) is not within the cumulative environmental operation range of the equipment of ECIE 100, 300, 400 (e.g., the cumulative environmental operation range of 10° C.-25° C.), then, in operation 605, DCIM 111 deactivates the economizer to reduce the transfer of heat/cooling between the internal environment of the edge container and the external environment. Such a deactivated economizer is shown in FIGS. 3 and 4B. For example, in one embodiment, external heat exchanger 107 is in a retracted position (fins 201 folded downward) for a deactivated economizer as shown in FIG. 3, and where, in one embodiment, internal heat exchanger blocking baffle is closed 403 and the plenum separator window is open 404 for a deactivated economizer as shown in FIG. 4B.

Upon deactivating the economizer, DCIM 111 extracts the environmental specifications for each equipment of ECIE 100, 300, 400 in operation 601 to account for any equipment newly installed within ECIE 100, 300, 400 and runs continuously to account for changes in environmental readings over time.

In an alternative embodiment, upon deactivating the economizer, DCIM 111 extracts a further reading of an environmental condition (e.g., temperature, pressure, humidity, etc.) in operation 603, such as from an external environment (e.g., outside ECIE 100, 300, 400) and/or the internal environment (e.g., inside ECIE 100, 300, 400), if there was no equipment newly installed within ECIE 100, 300, 400 and runs continuously to account for changes in environmental readings over time.

If, however, the reading of the environmental condition is within the cumulative environmental operation range of the equipment of ECIE 100, 300, 400, then, in operation 606, DCIM 111 activates the economizer to increase the transfer of heat/cooling between the internal environment of the edge container and the external environment. Such an activated economizer is shown in FIG. 4A. For example, in one embodiment, the internal heat exchanger blocking baffle is open 401 and the plenum separator window is closed 402 for an activated economizer as shown in FIG. 4A. In another example, fins 201 of external heat exchanger 107 are folded upward for an activated economizer as shown in FIGS. 1 and 2.

Upon activating the economizer, DCIM 111 extracts the environmental specifications for each equipment of ECIE 100, 300, 400 in operation 601 to account for any equipment newly installed within ECIE 100, 300, 400 and runs continuously to account for changes in environmental readings over time.

In an alternative embodiment, upon activating the economizer, DCIM 111 extracts a further reading of an environmental condition (e.g., temperature, pressure, humidity, etc.) in operation 603, such as from an external environment (e.g., outside ECIE 100, 300, 400) and/or the internal environment (e.g., inside ECIE 100, 300, 400), if there was no equipment newly installed within ECIE 100, 300, 400 and runs continuously to account for changes in environmental readings over time.

Additionally, the principles of the present disclosure take into consideration the operational limits of classes of data center equipment, such as from the American Society of Heating, Refrigerating and Air-Conditioning Engineers (ASHRAE) standards, for reducing the energy consumed in connection with transferring heat/cooling between an internal environment of the edge container of the edge data center and an external environment as discussed below in connection with FIG. 7.

FIG. 7 is a flowchart of a method 700 for reducing energy consumed by ACU 102 (FIG. 1) in connection with transferring heat/cooling between an internal environment of the edge container of the edge data center and an external environment using operational limits of classes of data center equipment and desired setpoints within an operational range in accordance with an embodiment of the present disclosure.

Referring to FIG. 7, in conjunction with FIGS. 1-3, 4A-4B, and 5-6, in operation 701, DCIM 111 extracts the operational limits (e.g., 15° C.-32° C., 5° C.-40° C., 5° C.-45° C.) for all the equipment (e.g., IT equipment of IT equipment racks 101, ACUs 102, economizer) of ECIE 100, 300, 400 as well as extracts the maximum operational limit of a class or classes (e.g., ASHRAE) of the data center equipment (e.g., IT equipment of IT equipment racks 101) of ECIE 100, 300, 400. It is noted that such operational limits apply to various environmental conditions, such as temperature, pressure, humidity, etc.

In one embodiment, DCIM 111 extracts the operational limits (e.g., 15° C.-32° C.) for all the equipment (e.g., IT equipment of IT equipment racks 101) of ECIE 100, 300, 400 from data stored on the equipment. In one embodiment, DCIM 111 extracts the operational limits for all the equipment of ECIE 100, 300, 400 from data stored on a database in the data center. In one embodiment, DCIM 111 extracts the operational limits for all the equipment of ECIE 100, 300, 400 from public records (e.g., product datasheets). In one embodiment, DCIM 111 extracts the operational limits for all the equipment of ECIE 100, 300, 400 by receiving such information from the operators of ECIE 100, 300, 400 and internal equipment. In one embodiment, if multiple operational limits for the same equipment are extracted by DCIM 111, then DCIM 111 averages such limits or selects the lowest or highest operational limit as corresponding to the operational limit for the equipment in question.

In one embodiment, DCIM 111 extracts the operational limit (e.g., 5° C.-40° C.) of a class (e.g., class A3) or classes of data center equipment (e.g., IT equipment of IT equipment racks 101) of ECIE 100, 300, 400 from standards, such as the ASHRAE standards. The “operational limit,” as used herein, refers to the minimum and maximum allowable value (e.g., minimum of 5° C. and maximum of 40° C.) of an environmental conditional (e.g., temperature, humidity, pressure, etc.) that should be maintained when the equipment in question is operating. In one embodiment, such standards are maintained in a data structure (e.g., table) stored in a data storage (e.g., data storage 511, 515) of ECIE 100, 300, 400.

In operation 702, DCIM 111 initializes a desired setpoint (e.g., 20° C.) within the cumulative operational limits of all equipment and within the operational limits of a class (e.g., A3) of data center equipment pertaining to the equipment in question (e.g., IT equipment of IT equipment racks 101). A “setpoint,” as used herein, refers to the value (e.g., 20° C.) of an environmental condition (e.g., temperature, pressure, humidity, etc.) that should not be exceeded when operating the equipment in question, where such a value may be adjusted based on readings of environmental conditions as discussed below. A “desired setpoint,” as used herein, refers to the setpoint that the equipment in question should not exceed while operating.

In one embodiment, DCIM 111 initializes such a desired setpoint based on a percentage (e.g., 90%) of the maximum value of the cumulative operational range for all the equipment of ECIE 100, 300, 400. In one embodiment, DCIM 111 initializes such a desired setpoint based on averaging the optimal setpoints for each equipment of ECIE 100, 300, 400 and ensures that value is within the cumulative operational range for all the equipment of ECIE 100, 300, 400. In one embodiment, a desired setpoint is set by the operator of the equipment (e.g., IT equipment of IT equipment racks 101). In one embodiment, the desired setpoint is set to a temperature where the IT equipment of IT equipment racks 101 operates as efficiently as possible and there is less risk for long term failures.

In operation 703, DCIM 111 extracts a reading of an external environmental condition, such as temperature, pressure, humidity, etc. In one embodiment, such a reading is extracted from the external environment (e.g., outside ECIE 100, 300, 400). As stated above, an “environmental condition,” as used herein, refers to a state of the environment, such as the temperature, pressure, humidity, etc. of the environment.

In one embodiment, DCIM 111 extracts such a reading from one or more sensors 115, which are placed external to ECIE 100, 300, 400. Examples of such sensors 115 include, but are not limited to, pressure sensors (e.g., differential air pressure sensor), temperature sensors (e.g., DX2-T1 by Raritan®), humidity sensors (e.g., DX2-T1H1 by Raritan®), etc.

In operation 704, DCIM 111 determines if the reading of the external environmental condition is greater than the ACU setpoint (not the desired setpoint). The ACU setpoint, as used herein, refers to the setpoint of ACU 102. In one embodiment, such a setpoint was previously established in operation 702, 707, 710 or 712. It is noted that the current ACU setpoint may not match the desired setpoint. The ACU setpoint may be higher than the desired setpoint to improve ACU efficiency and reduce cooling cost.

If the reading of the external environmental condition is not greater than the ACU setpoint, then, in operation 705, DCIM 111 determines whether the reading of the external environmental condition is greater than the desired setpoint for the IT equipment (obtained in operation 702).

If the reading of the external environmental condition is not greater than the desired setpoint for the IT equipment, then, in operation 706, DCIM 111 activates the economizer, if not previously activated. As previously discussed, activation of the economizer may involve folding fins 201 of external heat exchanger 107 thereby allowing the economizer to increase the transfer of heat/cooling between the internal environment of the edge container and the external environment. Furthermore, activation of the economizer may involve having the internal heat exchanger blocking baffle being open 401 and the plenum separator window being closed 402 thereby allowing the economizer to transfer heat/cooling between the internal environment of the edge container and the external environment.

In operation 707, DCIM 111 sets the setpoint of ACU 102 to correspond to the desired setpoint. A further reading of an external environmental condition, such as temperature, pressure, humidity, etc., is extracted from the external environment (e.g., outside ECIE 100, 300, 400) by DCIM 111 in operation 703.

Referring to operation 705, if, however, the reading of the external environmental condition (e.g., 25° C.) is greater than the desired setpoint for the IT equipment (e.g., 23° C.), then, in operation 708, DCIM 111 determines whether the ACU setpoint is greater than or equal to the maximum allowable operating condition of the cumulative operation range of equipment or class of data center equipment, whichever is lower (e.g., 40° C.) (corresponds to the values extracted in operation 701).

Furthermore, referring to operation 704, if, however, the reading of the external environmental condition (e.g., 42° C.) is greater than the ACU setpoint (e.g., 40° C.), then, in operation 708, DCIM 111 determines whether the ACU setpoint is greater than or equal to the maximum allowable operating condition of the cumulative operation range of equipment or class of data center equipment, whichever is lower (e.g., 40° C.) (corresponds to the values extracted in operation 701).

If the ACU setpoint is greater than or equal to the maximum allowable operating condition of the cumulative operation range of equipment or class of data center equipment, whichever is lower, then, in operation 709, DCIM 111 issues a warning notification indicating that one or more pieces of equipment (e.g., IT equipment of IT equipment racks 101) is operating outside its limits (e.g., outside the limits established by a standard and/or outside operational limits). In one embodiment, such a warning notification is issued to an administrator, such as electronically (e.g., e-mail, text message). In one embodiment, such a notification includes additional information as to what limit was exceeded and an identification (e.g., serial number) of the equipment in question so that the operator may quickly locate the equipment operating outside its limits. In one embodiment, in conjunction with such a notification, DCIM 111 may institute a shutdown operation of the equipment operating outside its limits in order to protect the impacted equipment.

After issuing the warning notification, in operation 710, DCIM 111 sets ACU 102 to its maximum cooling capacity.

Afterwards, DCIM 111 extracts a further reading of an external environmental condition, such as temperature, pressure, humidity, etc., from the external environment (e.g., outside ECIE 100, 300, 400) in operation 703.

Referring to operation 708, if, however, the ACU setpoint is not greater than or equal to the maximum allowable operating condition of the cumulative operation range of equipment or class of data center equipment, whichever is lower, then, in operation 711, DCIM 111 activates the economizer, if not previously activated. In this manner, the economizer will help ACU 102 to reach the new setpoint faster. As previously discussed, the activation of the economizer may involve folding fins 201 of external heat exchanger 107 thereby allowing the economizer to transfer heat/cooling between the internal environment of the edge container and the external environment. Furthermore, activation of the economizer may involve having internal heat exchanger blocking baffle being open 401 and the plenum separator window being closed 402 thereby allowing the economizer to transfer heat/cooling between the internal environment of the edge container and the external environment.

Upon activating the economizer, DCIM 111 matches the ACU setpoint to the external environmental condition reading (e.g., 25° C.) in operation 712.

After matching the ACU setpoint to the external environmental condition reading (e.g., 25° C.), in operation 713, DCIM 111 determines whether the reading of the external environmental condition (e.g., 25° C.) is equal to the ACU setpoint.

If the reading of the external environmental condition is not equal to the ACU setpoint, then DCIM 111 extracts a further reading of an external environmental condition, such as temperature, pressure, humidity, etc., from the external environment (e.g., outside ECIE 100, 300, 400) in operation 703.

If, however, the reading of the external environmental condition is equal to the ACU setpoint, then, in operation 714, DCIM 111 deactivates the economizer. As previously discussed, deactivation of the economizer may involve folding down fins 201 of external heat exchanger 107 thereby causing the economizer to reduce the transfer of heat/cooling between the internal environment of the edge container and the external environment. Furthermore, deactivation of the economizer may involve having the internal heat exchanger blocking baffle closed 403 and the plenum separator window open 404 thereby preventing the economizer from transferring heat/cooling between the internal environment of the edge container and the external environment.

After deactivating the economizer, DCIM 111 extracts a further reading of an external environmental condition, such as temperature, pressure, humidity, etc., from the external environment (e.g., outside ECIE 100, 300, 400) in operation 703.

In this manner, the energy consumed for cooling equipment (e.g., IT equipment) in the edge container of the edge data center is reduced. In particular, the heat/cooling transfer between the internal and external environments of the edge container is improved thereby reducing the overall mechanical cooling power consumption.

Furthermore, the principles of the present disclosure improve the technology or technical field involving edge data centers. As discussed above, edge data centers include decentralized computing resources, which may be installed in “edge containers,” located as close as possible to the end user in order to reduce latency, save bandwidth, and enhance the overall digital experience. Edge containers are becoming increasing popular due to their quick deployment, scalability capacity for implementation anywhere, and the ability to protect the internal computing resources. Edge containers typically employ a mechanical-based cooling system to provide cooling to the IT equipment. IT equipment includes computers and associated peripheral devices, computer operating systems, utility/support software, communications hardware and software, etc. Cooling systems in such edge containers require external electricity, which may be extensive. As a result, the energy consumed for cooling the IT equipment in the edge container needs to be reduced in order to more efficiently use power resources.

Embodiments of the present disclosure improve such technology by utilizing an edge container of an edge data center that includes information technology racks holding information technology (IT) equipment. The IT equipment includes computers and associated peripheral devices, computer operating systems, utility/support software, communications hardware and software, etc. Furthermore, the edge container includes at least one air conditioning unit configured to provide cool air to a cold aisle which enters an inlet side of the information technology racks. Additionally, the edge container includes an economizer that includes an internal heat exchanger and an external heat exchanger. In one embodiment, a cumulative environmental operation range (e.g., range of temperature, range of humidity, range of pressure) of all the equipment of the edge container is determined. For example, if a first IT equipment has an operational range of 10° C.-40° C. and a second IT equipment has an operational range of 5° C.-35° C., then the cumulative environmental operation range is 10° C.-35° C. since this is the safe operational range for the first and second IT equipment. The economizer is then activated to increase the transfer of heat/cooling between an internal environment of the edge container and an external environment in response to a reading of an environmental condition (e.g., temperature, pressure, humidity, etc.) in the external environment that would lead to reduced energy consumption for the cooling equipment to maintain environmental conditions within the cumulative environmental operation range. An “environmental condition,” as used herein, refers to a state of the environment, such as the temperature, pressure, humidity, etc. of the environment. If, however, the reading of the environmental condition (e.g., temperature, pressure, humidity, etc.) in the external environment would not lead to reduced energy consumption for the cooling equipment to maintain environmental conditions within the cumulative environmental operation range, then the economizer is deactivated thereby reducing the transfer of heat/cooling between the internal environment of the edge container and the external environment. In this manner, the energy consumed for cooling equipment (e.g., IT equipment) in the edge container of the edge data center is reduced. In particular, the heat/cooling transfer between the internal and external environments of the edge container is improved thereby reducing the overall mechanical cooling power consumption. Furthermore, in this manner, there is an improvement in the technical field involving edge data centers.

The technical solution provided by the present disclosure cannot be performed in the human mind or by a human using a pen and paper. That is, the technical solution provided by the present disclosure could not be accomplished in the human mind or by a human using a pen and paper in any reasonable amount of time and with any reasonable expectation of accuracy without the use of a computer.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. An edge container of an edge data center, comprising:
information technology racks holding information technology equipment;
at least one air conditioning unit configured to provide cool air to a cold aisle which enters an inlet side of the information technology racks; and
an economizer comprising an internal heat exchanger and an external heat exchanger, wherein the economizer is activated to increase a transfer of heat/cooling between an internal environment of the edge container and an external environment in response to a reading of an external environmental condition being below a temperature of exhaust air in a hot aisle of the edge container which exits an outlet side of the information technology racks.

2. The edge container of the edge data center as recited in claim 1, wherein the environmental condition is selected from the group consisting of temperature, humidity, and pressure.

3. The edge container of the edge data center as recited in claim 1, wherein the economizer is configured to control an amount of heat transfer via folding up or down of fins of the external heat exchanger.

4. The edge container of the edge data center as recited in claim 3, wherein the fins of the external heat exchanger are folded down in response to deactivating the economizer, wherein the fins of the external heat exchanger are folded up in response to activating the economizer.

5. The edge container of the edge data center as recited in claim 1, wherein the economizer is configured to control an amount of heat transfer via exposing or blocking fins of the internal heat exchanger.

6. The edge container of the edge data center as recited in claim 1 further comprising:
an aisle separator configured to ensure that the cold aisle is separated from the hot aisle of the edge container.

7. The edge container of the edge data center as recited in claim 6, wherein the hot aisle is a chamber for hot air exiting the information technology racks.

8. The edge container of the edge data center as recited in claim 1 further comprising:
a plenum separator configured to separate airflow exhausted from the information technology racks and airflow exhausted to an air conditioning unit plenum before entering the at least one air conditioning unit.

9. The edge container of the edge data center as recited in claim 1, wherein the heat is transferred from the internal environment of the edge container to the external environment via the economizer.

10. The edge container of the edge data center as recited in claim 9, wherein external air flows through fins of the external heat exchanger, wherein cooler external air removes heat from the hot aisle of the edge container.

11. A method for transferring heat between an internal environment of an edge container of an edge data center and an external environment, the method comprising:
extracting a reading of an external environmental condition; and
activating an economizer of the edge container to increase a transfer of heating or cooling between the internal environment of the edge container and the external environment in response to the read environmental condition being below a temperature of exhaust air in a hot aisle of the edge container which exits an outlet side of information technology racks.

12. The method as recited in claim 11 further comprising:
determining a cumulative environmental operation range of equipment within the edge container, wherein the equipment comprises information technology equipment, at least one air conditioning unit, and the economizer of the edge container.

13. The method as recited in claim 11, wherein the external environmental condition is selected from the group consisting of temperature, humidity, and pressure.

14. The method as recited in claim 11 further comprising:
deactivating the economizer of the edge container to reduce a transfer of heat between the internal environment of the edge container and the external environment in response to the read external environmental condition not being below the temperature of the exhaust air in the hot aisle of the edge container which exits the outlet side of the information technology racks.

15. The method as recited in claim 11, wherein the economizer is configured to control an amount of heat transfer via folding up or down of fins of an external heat exchanger of the economizer.

16. The method as recited in claim 15, wherein the fins of the external heat exchanger are folded down in response to deactivating the economizer, wherein the fins of the external heat exchanger are folded up in response to activating the economizer.

17. The method as recited in claim 11, wherein the economizer is configured to control an amount of heat transfer via exposing or blocking fins of an internal heat exchanger of the economizer.

18. The method as recited in claim 11 further comprising:
initializing a desired setpoint within operational limits of all equipment within the edge container and within an operational limit of a class of data center equipment;
activating, if not previously activated, the economizer of the edge container in response to the reading of the external environmental condition not exceeding an air conditioning unit setpoint and in response to the reading of the external environmental condition not exceeding the desired setpoint; and
setting the air conditioning unit setpoint to correspond to the desired setpoint in response to the reading of the external environmental condition not exceeding the desired setpoint.

19. The method as recited in claim 11 further comprising:
activating, if not previously activated, the economizer of the edge container in response to the reading of the external environmental condition being greater than an air conditioning unit setpoint and in response to the air conditioning unit setpoint not being greater than or equal to a maximum allowable operating condition of a cumulative operation range of equipment or class of data center equipment, whichever is lower;
matching the air conditioning unit setpoint to the reading of the external environmental condition upon activating, if not previously activated, the economizer; and
deactivating the economizer of the edge container in response to the reading of the external environmental condition equaling the air conditioning unit setpoint.

20. A computer program product for transferring heat between an internal environment of an edge container of an edge data center and an external environment, the computer program product comprising one or more computer readable storage mediums having program code embodied therewith, the program code comprising programming instructions for:
extracting a reading of an external environmental condition; and
activating an economizer of the edge container to increase a transfer of heating or cooling between the internal environment of the edge container and the external environment in response to the read environmental condition being below a temperature of exhaust air in a hot aisle of the edge container which exits an outlet side of information technology racks.
